(19) United States
(12) Patent Application Publication
(10) Pub. No.: US 2008/0018365 A1
(43) Pub. Date: Jan. 24, 2008

(54) Coil Load Drive Output Circuit

(75) Inventor: Toshiro Okubo, Kyoto (JP)

Correspondence Address: ROHM CO., LTD.;C/O KEATING & BENNETT, LLP, 8180 GREENSBORO DRIVE, SUITE 850, MCLEAN, VA, 22102, US

(73) Assignee: ROHM CO., LTD., Ukyo-ku, Kyoto (JP)

(21) Appl. No.: 11/569,946

(22) PCT Filed: Jun. 1, 2005
(86) PCT No.: PCT/JP05/10039

§ 371 Date: Jul. 25, 2007

(30) Foreign Application Priority Data
Jun. 2, 2004 (JP) 2004-164291

(51) Int. Cl. H03K 3/00

(52) U.S. Cl. 327/110

(57) ABSTRACT

A coil load drive output circuit permits a reduction in radiation noise caused by switching. The coil load drive output circuit includes first and second control transistors which output a power supply-side drive transistor control voltage; first and second current-limiting impedance elements which limit the currents flowing to the first and second control transistors; third and fourth control transistors which output a ground-side drive transistor control voltage; third and fourth current-limiting impedance elements which limit current flowing to the third and fourth control transistors; a power supply-side drive transistor and a ground-side drive transistor each of which is controlled by the power supply-side drive transistor control voltage or the ground-side drive transistor control voltage and which output the drive voltage for the coil load; and a power supply-side detection transistor and a ground-side detection transistor each of which is controlled by the power supply-side drive transistor control voltage or the ground-side drive transistor control voltage and which, when turned ON, forcibly turn OFF the ground-side drive transistor or the power supply-side drive transistor.

### BACKGROUND OF THE INVENTION

1. Field of the Invention

The present invention relates to a coil load drive output circuit for driving a coil load such as a motor or actuator.

2. Description of the Related Art

Normally, in a device that uses a pulse width modulation (PWM) pulse to drive a coil load, the effect of crosstalk or the like to other signals is a problem because the radiation noise that is produced by the switching of the device is large. In particular, because the current output capability of the drive transistor of the coil load drive output circuit that outputs the drive voltage for the coil load is large, the radiation noise caused by the switching is large.

On the other hand, as a countermeasure for reducing the noise caused by the switching of the general output circuit, proposals such as those shown in Japanese Application Laid Open No. H6-152374 (Patent Document 1) and Japanese Application Laid Open No. H11-317653 (Patent Document 2) below, for example, have been made. These output circuits attempt noise reduction by gradually turning on the power supply-side drive transistor or ground-side drive transistor. By gradually turning on the power supply-side drive transistor or ground-side drive transistor, these output circuits also attempt to prevent a short circuit current in the power supply-side drive transistor and ground-side drive transistor.

However, if the load that the output circuit drives is a coil load, that is, if the output circuit is a coil load drive output circuit, a particular phenomenon occurs as a result of the inductive properties of the coil load. For example, as shown in FIG. 4, when the power supply-side drive transistor 111 that supplies a current I_{1,} from the output terminal OUT to the coil load 2 is turned off by the switching, and because the current continues to flow as a result of the inductive properties of the coil load 2, the regeneration current I₂ flows to the coil load 2 via a parasitic diode 113 that is arranged in parallel with the ground-side drive transistor 112. Hence, the voltage of the output terminal OUT drops sharply from the power supply voltage V_{CC} to below the ground potential, whereby radiation noise is produced.

This radiation noise can usually be dealt with by mounting an anti-noise component such as a condenser in the required location. But, reducing the radiation noise itself is important from the perspective of performance and cost, and so forth.

### SUMMARY OF THE INVENTION

In order to overcome the problems described above, preferred embodiments of the present invention provide a coil load drive output circuit that permits a reduction in the radiation noise caused by switching.

A coil load drive output circuit according to a preferred embodiment of the present invention includes first and second control transistors, serially connected between a power supply potential and a ground potential, from a midpoint of which a power supply-side drive transistor control voltage is output; first and second current-limiting impedance elements which limit a current flowing to the first and second control transistors, respectively; third and fourth control transistors, serially connected between a power supply potential and a ground potential, from a midpoint of which a ground-side drive transistor control voltage is output; third and fourth current-limiting impedance elements which limit a current flowing to the third and fourth control transistors, respectively; a power supply-side drive transistor and a ground-side drive transistor, serially connected between a power supply potential and a ground potential, each of which is controlled by the power supply-side drive transistor control voltage or the ground-side drive transistor control voltage and from a midpoint of which a drive voltage for driving the coil load is output; a power supply-side detection transistor which is controlled by the power supply-side drive transistor control voltage and which, when turned ON, forcibly turns OFF the ground-side drive transistor; and a ground-side detection transistor which is controlled by the ground-side drive transistor control voltage and which, when turned ON, forcibly turns OFF the power supply-side drive transistor.

Preferably, the power supply-side drive transistor is a P-type MOS transistor and the ground-side drive transistor is an N-type MOS transistor, and the second and third current-limiting impedance elements have larger resistance values than the resistance values of the first and fourth current-limiting impedance elements.

Alternatively, the power supply-side drive transistor and ground-side drive transistor are preferably both N-type MOS transistors and the first and third current-limiting impedance elements have larger resistance values than the resistance values of the second and fourth current-limiting impedance elements.

According to the present preferred embodiment of the present invention, the coil load drive output circuit provides current-limiting impedance elements that limit the current flowing to the respective control transistors. Hence, the power supply-side drive transistor and ground-side drive transistor can be gradually turned on and off to permit a reduction in the radiation noise caused by switching.

Other features, elements, processes, steps, characteristics and advantages of the present invention will become more apparent from the following detailed description of preferred embodiments of the present invention with reference to the attached drawings.

### BRIEF DESCRIPTION OF THE DRAWINGS

FIG. 1 is a circuit diagram of a coil load drive output circuit according to a preferred embodiment of the present invention.

FIG. 2 is a waveform diagram showing a waveform that is produced in the respective parts of the circuit diagram of FIG. 1.

FIG. 3 is a circuit diagram of a coil load drive output circuit according to another preferred embodiment of the present invention.

FIG. 4 is a circuit diagram illustrating a phenomenon during switching.

### DETAILED DESCRIPTION OF PREFERRED EMBODIMENTS

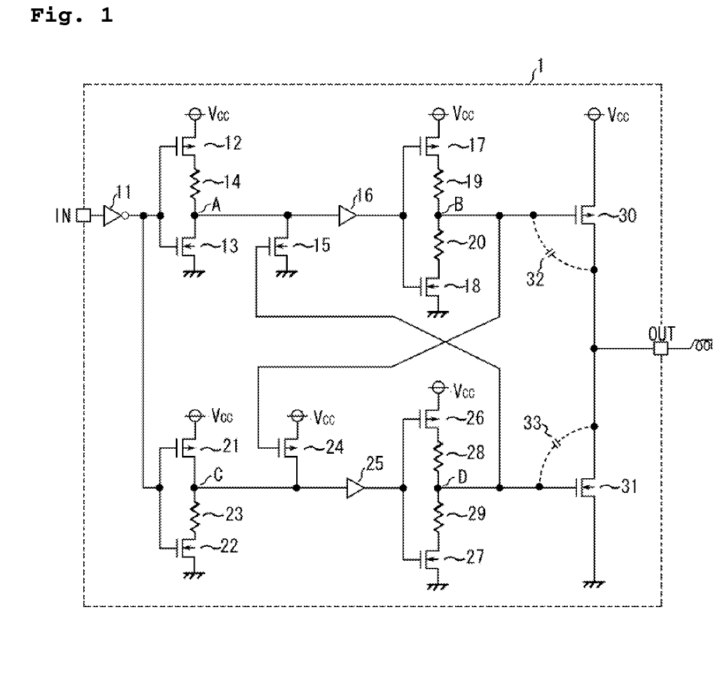

Preferred embodiments of the present invention will be described hereinbelow with reference to the drawings. FIG. 1 is a circuit diagram of a coil load drive output circuit 1 according to a preferred embodiment of the present invention. An inverter 11 inverts a high-level or low-level input signal (PWM signal) that is input from a motor control circuit or actuator control circuit (outside the drawing) to an input terminal IN and outputs the result. A P-type MOS transistor 12 and an N-type MOS transistor 13 are connected in series between the power supply potential V_{CC} and ground potential and the output signal of the inverter 11 is input to the P-type MOS transistor 12 and the N-type MOS transistor 13 and inverted and output from the midpoint therebetween, that is, from node A. Current-limiting impedance element 14 limits the current flowing to the P-type MOS transistor 12. Element 15 is a ground-side detection transistor which is an N-type MOS transistor and the ground-side detection transistor 15 is connected to node A and controlled by the voltage at node D (described subsequently), that is, by the ground-side drive transistor control voltage. Buffer 16 shapes the voltage waveform of node A. 17 and 18 are a first control transistor which is a P-type MOS transistor and a second control transistor which is an N-type MOS transistor, respectively. The first control transistor 17 and the second control transistor 18 are connected in series between the power supply potential V_{CC} and ground potential and the output signal of the buffer 16 is input to the first control transistor 17 and the second control transistor 18 and the power supply-side drive transistor control voltage is output from the midpoint therebetween that is, from node B. First and second current-limiting impedance elements 19 and 20, respectively, limit the current flowing to the first and second control transistors 17 and 18, respectively.

Additionally, a P-type MOS transistor 21 and an N-type MOS transistor 22 are serially connected between the power supply potential V_{CC} and ground potential and the output signal of the inverter 11 is input to the P-type MOS transistor 21 and the N-type MOS transistor 22 and then inverted and output from the midpoint therebetween, that is, node C. Current-limiting impedance element 23 limits the current flowing to the N-type MOS transistor 22. A power supply-side detection transistor 24 which is preferably a P-type MOS transistor is connected to node C and controlled by the voltage at node B, that is, the power supply-side drive transistor control voltage. Buffer 25 shapes the voltage waveform of at node C. A third control transistor 26 which is preferably a P-type MOS transistor and a fourth control transistor 27 which is preferably an N-type MOS transistor. The third control transistor 26 and the fourth control transistor 27 are serially connected between the power supply potential V_{CC} and ground potential and the output signal of the buffer 25 is input to the third control transistor 26 and the fourth control transistor 27 and a ground-side drive transistor control voltage is output from the midpoint therebetween, that is, from node D. 28 and 29 are third and fourth current-limiting impedance elements. The third and fourth current-limiting impedance elements 28 and 29, respectively, limit the current flowing to the third and fourth control transistors 26 and 27.

Additionally, 30 and 31 are, respectively, a power supply-side drive transistor which is a P-type MOS transistor and a ground-side drive transistor which is an N-type MOS transistor. The power supply-side drive transistor 30 and the ground-side drive transistor 31 are serially connected between the power supply potential V_{CC} and ground potential, each controlled by the power supply-side drive transistor control voltage or ground-side drive transistor control voltage, andadrivevoltage for driving, via the output terminal OUT, the coil load 2 is output from the midpoint therebetween. In FIG. 1, in order to facilitate understanding, a parasitic capacitance 32 across the drain and gate of the power supply-side drive transistor 30 and a parasitic capacitance 33 between the drain and gate of the ground-side drive transistor 31 are shown. The same circuit as that of the coil load drive output circuit 1 should be provided on the other side (not illustrated) of the coil load 2.

The current-limiting impedance elements 14, 19, 20, 23, 28, and 29 are resistors. The current-limiting impedance element 14 has a resistance value of a magnitude that allows the voltage of the node A to be kept at a low level when the ground-side detection transistor 15 is turned ON, even when the P-type MOS transistor 12 is turned ON. The current-limiting impedance element 23 has a resistance value of a magnitude that allows the voltage of node C to be kept at a high level when the power supply-side detection transistor 24 is turned ON, even when the N-type MOS transistor 22 is turned ON. The resistance values of the first current-limiting impedance element 19 and fourth current-limiting impedance element 29 are the same or almost the same (1KΩ to 2KΩ, for example), and are smaller than the resistance values of the second current-limiting impedance element 20 and third current-limiting impedance element 28 (10KΩ to 30KΩ, for example).

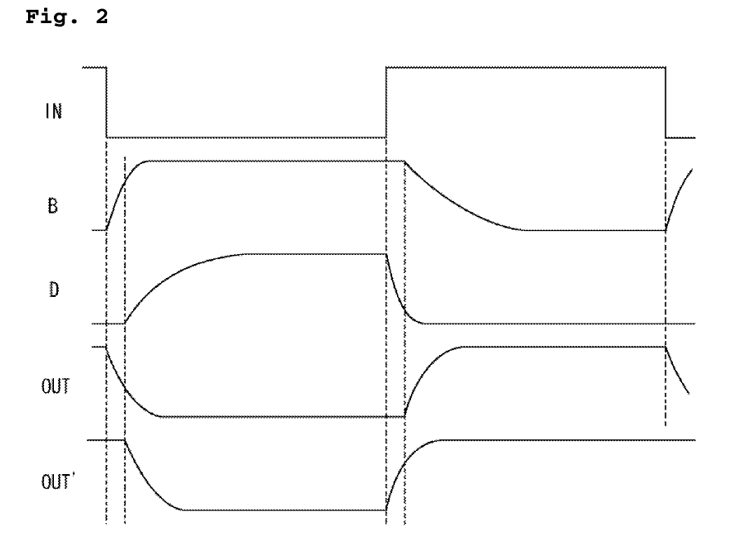

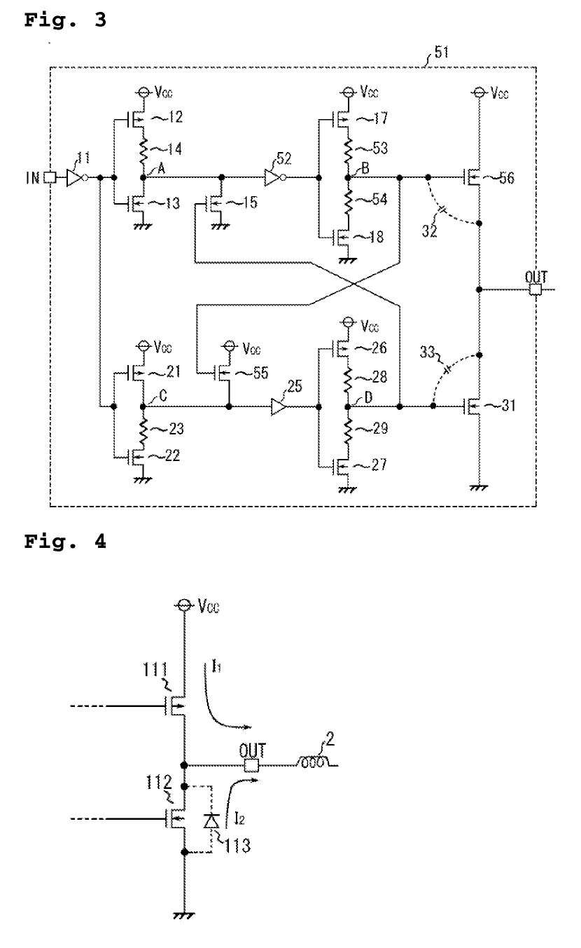

The operation of the coil load drive output circuit 1 will now be described on the basis of the waveform diagram of FIG. 2. First, a case where current is flowing in the direction from the output terminal OUT to the coil load 2 will be described. In FIG. 2, the OUT waveform indicates a voltage waveform of the output terminal OUT in this case and OUT' indicates the voltage waveform of the output terminal OUT in a case where current is flowing in the direction from the coil load 2 to the output terminal OUT (described subsequently) . When the input signal from the input terminal IN changes from the high level to the low level, node A is at the low level and, because the first control transistor 17 is ON, the voltage at node B rises at a time constant that is determined by the resistance value of the impedance element 19 and the capacitance value of the parasitic capacitance 32. The ON resistance of the power supply-side drive transistor 30 gradually rises as the voltage at node B changes. As the coil load 2 continues to allow a current to flow as a result of its inductive properties, the voltage of the output terminal OUT gradually falls. Therefore, the voltage of the output terminal OUT does not drop sharply and, therefore, the radiation noise is reduced.

Thereupon, because the power supply-side detection transistor 24 is turned ON, node C is held at a high level and node D is held at a low level. Hence, the ground-side drive transistor 31 is forcibly turned OFF irrespective of the input signal from the input terminal IN. Then, the voltage at node B rises further and, when the voltage across the gate and source of the power supply-side drive transistor 30 is smaller than a threshold value, the power supply-side drive transistor 30 is then at the so-called subthreshold region and the ON resistance rises sharply so that the power supply-side drive transistor 30 starts to turn OFF. Thus, because the power supply-side detection transistor 24 also starts to turn OFF at the same time, the node C is then at the low level. The voltage of node D rises at a time constant that is determined by the capacitance value of the parasitic capacitance 33 and the resistance value of the impedance element 28 because the third control transistor 26 is turned ON.

Here, the impedance element 28 is larger than the resistance value of the impedance element 19. Hence, the voltage at node D rises more moderately than the voltage at node B. As a result, after the power supply-side drive transistor 30 in which a small current flows also at the subthreshold region turns off completely, current flows to the ground-side drive transistor 31. Therefore, the short circuit current in the two transistors 30 and 31 is minimized. In order to minimize the short circuit current, the voltage at node B must rise to the power supply potential V_{CC} relatively quickly. Hence, the impedance element 19 is smaller than the resistance value of the impedance element 28 as described earlier.

When the input signal from the input terminal IN changes from the low level to the high level, node C is at the high level and the fourth control transistor 27 is turned ON, whereby the voltage at node D drops at a time constant that is determined by the resistance value of the impedance element 29 and the capacitance value of the parasitic capacitance 33. The ON resistance of the ground-side drive transistor 31 gradually rises in accordance with the voltage change at node D. The coil load 2 continues to allow the current to flow as a result of its inductive properties. Hence, the voltage of the output terminal OUT drops a little, but is clamped by a parasitic diode (not shown) that is parallel to the ground-side drive transistor 31. Thereupon, as the ground-side detection transistor 15 is turned ON, node A is kept at the low level and node B is kept at the high level. Therefore, the power supply-side drive transistor 30 is forced OFF irrespective of the input signal from the input terminal IN. The voltage at node D then drops further and, when the voltage across the gate and source of the ground-side drive transistor 31 is smaller than the threshold value, the ground-side drive transistor 31 is then at the subthreshold region, the ON resistance rises sharply, and the ground-side drive transistor 31 starts to turn OFF. Thus, because the ground-side detection transistor 15 starts to turn OFF at the same time, node A is then at the high level. The voltage at node B gradually drops at a time constant that is determined by the resistance value of the impedance element 20 and the capacitance value of the parasitic capacitance 32 because the second control transistor 18 turns OFF. The voltage of the output terminal OUT gradually rises in accordance with the voltage at node B. Hence, the radiation noise is reduced.

A case where current is flowing in the direction from the coil load 2 to the output terminal OUT will be described next. The respective parts other than the output terminal OUT (waveform OUT' in FIG. 2) illustrate the same operation as that described above. When the input signal from the input terminal IN changes from the high level to the low level or from the low level to the high level, the voltage of the output terminal OUT falls or rises gradually in accordance with the voltage at node D. That is, the voltage of output terminal OUT starts to drop after the ground-side drive transistor 31 starts to turn ON, and starts to rise after the ground-side drive transistor 31 starts to turn OFF. Radiation noise is similarly also reduced in this case.

The coil load drive output circuit of another preferred embodiment of the present invention will be described next. As shown in FIG. 3, this coil load drive output circuit 51 is obtained by substituting the power supply-side drive transistor 30 which is a P-type MOS transistor in the coil load drive output circuit 1 for a power supply-side drive transistor 56 which is an N-MOS transistor. Accordingly, the power supply-side detection transistor 24 which is a P-type MOS transistor is substituted for apower supply-side detection transistor 55 which is an N-type MOS transistor, buffer 16 is substituted for an inversion buffer 52, the first current-limiting impedance element 19 is substituted for a first current-limiting impedance element 53 having a relatively large resistance value (of 10KΩ to 30KΩ, for example), and the second current-limiting impedance element 20 is substituted for a second current-limiting impedance element 54 having a relatively small resistance value (of 1KΩ to 2KΩ, for example) In the coil load drive output circuit 51, a voltage waveform at node B is the vertical inverse of the waveform in FIG. 2. But, the coil load drive output circuit 51 performs the same operation as that of the coil load drive output circuit 1, whereby the radiation noise is reduced.

In the coil load drive output circuit 1 or 51, since the ground-side detection transistor 15 and the power supply-side detection transistor 24 or 55 are provided, if the power supply-side drive transistor 30 or 56 is turned ON, the ground-side drive transistor 31 is forced OFF and, if the ground-side drive transistor 31 is turned ON, the power supply-side drive transistor 30 or 56 is forced OFF. As a result, the short circuit current in the power supply-side drive transistor 30 or 56 and the ground-side drive transistor 31 is automatically minimized. But, the gates of the first to fourth control transistors 17, 18, 26, and 27, respectively, can also be individually controlled to minimize the short circuit current.

A coil load drive output circuit has been described above with respect to the preferred embodiments of the present invention, but the present invention is not limited to the coil load drive output circuit described in the preferred embodiments and permits various design modifications within the scope of the present invention. For example, the current-limiting impedance elements 14 and 19 (or 53), 20 (or 54), 23, 28, and 29 have been described as preferably being resistors, but can also be constant current sources. Further, a capacitance can also be added proactively in addition to the parasitic capacitances 32 and 33.

While preferred embodiments of the present invention have been described above, it is to be understood that variations and modifications will be apparent to those skilled in the art without departing the scope and spirit of the present invention. The scope of the present invention, therefore, is to be determined solely by the following claims.

1. A coil load drive output circuits comprising:
first and second control transistors, serially connected between a power supply potential and a ground potential, from a midpoint of which a power supply-side drive transistor control voltage is output;
first and second current-limiting impedance elements which limit current flowing to the first and second control transistors, respectively;
third and fourth control transistors, serially connected between a power supply potential and a ground potential, from a midpoint of which a ground-side drive transistor control voltage is output;
third and fourth current-limiting impedance elements which limit current flowing to the third and fourth control transistors, respectively;
a power supply-side drive transistor and a ground-side drive transistor, serially connected between a power supply potential and a ground potential, each of which is controlled by the power supply-side drive transistor control voltage or the ground-side drive transistor control voltage and from a midpoint of which a drive voltage for driving the coil load is output;
a power supply-side detection transistor which is controlled by the power supply-side drive transistor control voltage and which, when turned ON, forcibly turns OFF the ground-side drive transistor; and
a ground-side detection transistor which is controlled by the ground-side drive transistor control voltage and which, when turned ON, forcibly turns OFF the power supply-side drive transistor.

2. The coil load drive output circuit according to claim 1, wherein
the power supply-side drive transistor is a P-type MOS transistor and the ground-side drive transistor is an N-type MOS transistor,
and the second and third current-limiting impedance elements have larger resistance values than the resistance values of the first and fourth current-limiting4 impedance elements.

3. The coil load drive output circuit according to claim 1, wherein
the power supply-side drive transistor and ground-side drive transistor are both N-type MOS transistors,
and the first and third current-limiting impedance elements have larger resistance values than the resistance values of the second and fourth current-limiting impedance elements.
